(19) United States
(12) Patent Application Publication
(10) Pub. No.: US 2005/0133940 A1
(43) Pub. Date: Jun. 23, 2005

(54) Method and structure for protecting an alignment mark

(76) Inventors: Mou-Jung Chen, Taoyuan County (TW); Chien-Hsien Song, Kaoshiung City (TW); Yui-Su Lee, Taichong County (TW); Chien-Yuan Lee, Taipei County (TW); Yue-Feng Chen, Hsinchu City (TW)

Correspondence Address: BIRCH STEWART KOLASCH & BIRCH, PO BOX 747, FALLS CHURCH, VA, 22040-0747, US

(21) Appl. No.: 10/865,746

(22) Filed: Jun. 14, 2004

(30) Foreign Application Priority Data
Dec. 23, 2003 (TW) 092136515

(51) Int. Cl. H01L 21/76; H01L 21/4763; H01L 23/544

(52) U.S. Cl. 257/797; 438/401

(57) ABSTRACT

A method and structure for protecting alignment marks. A substrate comprising a plurality of alignment marks is provided, wherein the alignment mark comprises a plurality of trenches. A plurality of protective patterns are formed on the substrate by depositing a protective layer and patterning the same to protect the alignment marks from damage during subsequent CMP process.

### BACKGROUND OF THE INVENTION

1. Field of the Invention

The present invention relates to a semiconductor manufacturing process and in particular to a method and a structure for protecting alignment marks on a semiconductor substrate.

2. Description of the Related Art

Lithography, a key step in the semiconductor integrated circuits manufacturing process, is used to pattern a film or form a mask before ion implantation. Proper alignment is critical to lithography. An alignment mark is formed on a wafer for precise alignment of the mask prior to lithography.

Referring to FIG. 1A, in a split gate flash memory fabrication process, a gate dielectric layer 102, a polysilicon layer 104, a silicon nitride layer 106 and a silicon oxide layer 108 are formed in order on alignment marks of a substrate. Next an oxide reverse etching (ODR) process is performed to remove a portion of the silicon oxide layer in the cell region (not shown), to eliminate the loading effect. In the ODR process, a mask pattern (not shown) is formed on the cell region to pattern the oxide region of the like area. The silicon oxide layer 108 over the alignment mark is uniformly etched without the protection of a mask pattern. Accordingly, as shown in FIG. 1B, the silicon oxide layer 108 over trenches 105 of the alignment mark 101 and neighboring substrate 103 are easily over etched.

Next, the silicon oxide layer 108 is planarized by chemical mechanical polishing process (CMP). Preferably, as shown in FIG. 1C, the silicon oxide layer 108, a portion of the silicon nitride layer 106 are removed, wherein a portion of the silicon nitride layer is remained. The polysilicon layer 104 over the alignment mark remains an original thickness and there should be a remained thin silicon nitride layer 106 to protect the polysilicon layer 104 thereunder. If the silicon oxide layer 108 is over etched in the ODR process, it may be easily over-polished during the subsequent CMP step, thus removing the entire silicon nitride layer 106 from the surface of the substrate and damaging the polysilicon layer 104 thereunder. The damaged polysilicon layer 104 will not have a uniform thickness over the alignment mark 101, thus the polysilicon layer 104 over the corner region 107 and 109 of the alignment mark 101 has different refraction. Consequently, a scanner cannot precisely align a mask to the corners 107 and 109 of the alignment mark 101. The described situation may occur also occurred in the fabrication of dynamic random access memory (DRAM).

### SUMMARY OF THE INVENTION

Accordingly, an object of the invention is to provide a structure and method for forming a protective pattern to protect alignment marks or the layers thereon from damage during subsequent polishing or etching processes.

To achieve the above objects, the present invention provides a method for protecting alignment marks. A substrate is provided, wherein the substrate comprises a plurality of alignment marks comprising a plurality of trenches. A protective layer is formed on the substrate and the protective layer is patterned to form a protective pattern on the substrate and adjacent to the trenches.

To achieve the above objects, the present invention provides a structure for protecting alignment marks, comprising a substrate, wherein the substrate comprises a plurality of alignment marks comprising a plurality of trenches, and a protective pattern disposed on the substrate and adjacent to the trenches.

A detailed description is given in the following embodiments with reference to the accompanying drawings.

### BRIEF DESCRIPTION OF THE DRAWINGS

The present invention can be more fully understood by reading the subsequent detailed description and examples with reference to the accompanying drawings, wherein:

FIGS. 1A˜1D are cross sections of conventional split gate FLASH or DRAM and alignment marks thereof;

FIG. 2A is a top view of an alignment mark of the present invention;

FIGS. 2B˜2D are cross sections of a process of a process for forming a protective pattern of the preferred embodiment;

FIG. 2E is a top view of an embodiment of the present invention, illustrating a protective pattern disposed on a substrate adjacent to a alignment mark;

FIG. 3 is a top view of another embodiment of the present invention, illustrating a protective pattern disposed on a substrate adjacent to an alignment mark;

FIG. 4 is a top view of further another embodiment of the present invention, illustrating a protective pattern disposed on a substrate adjacent to an alignment mark.

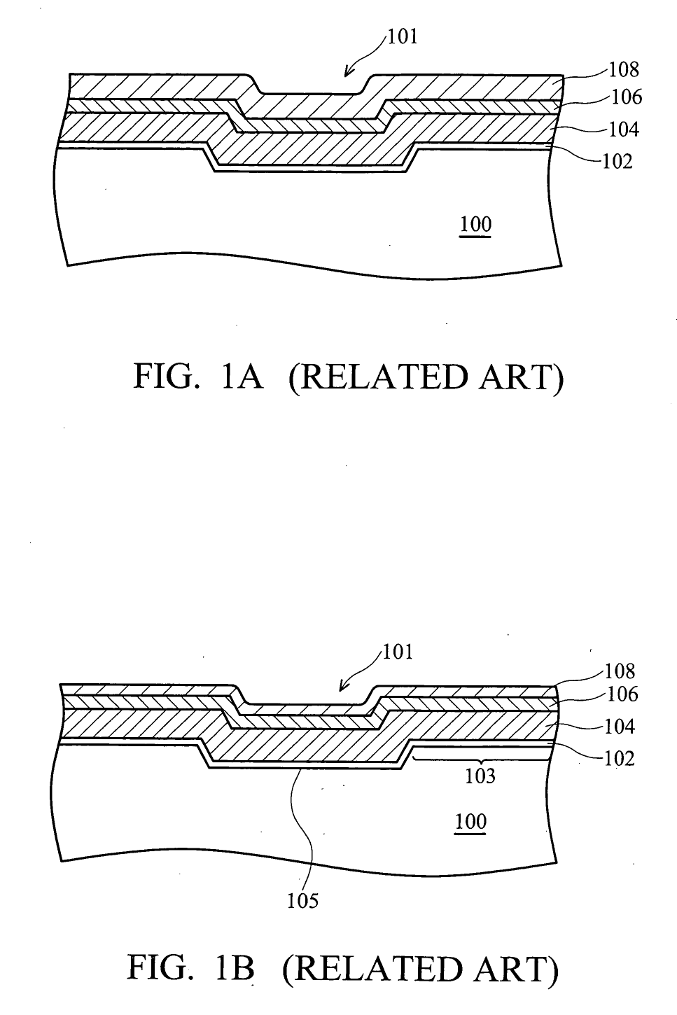

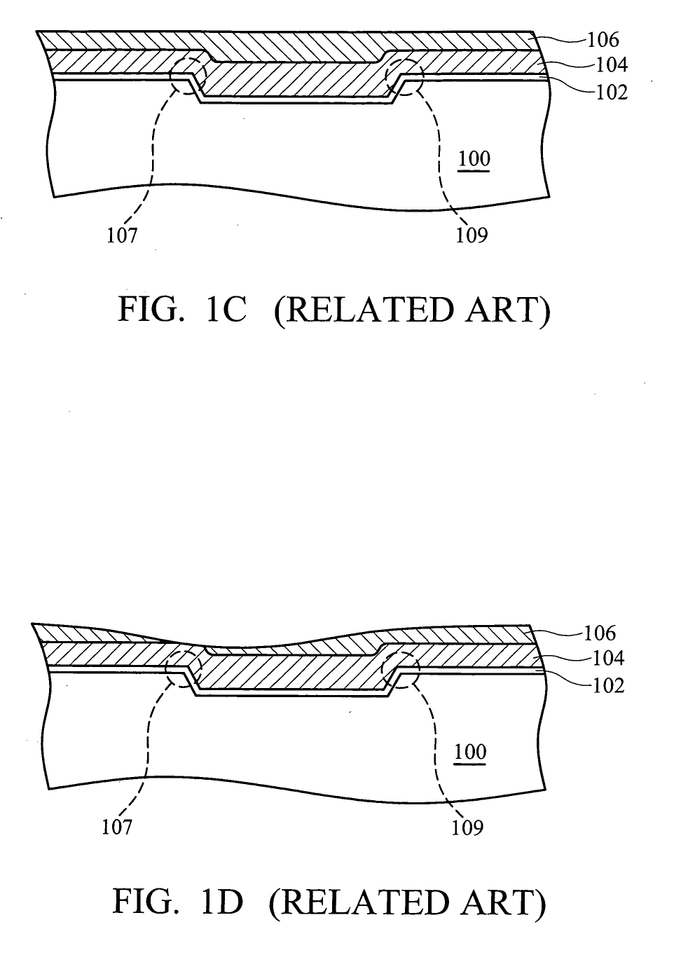

### DETAILED DESCRIPTION OF THE INVENTION

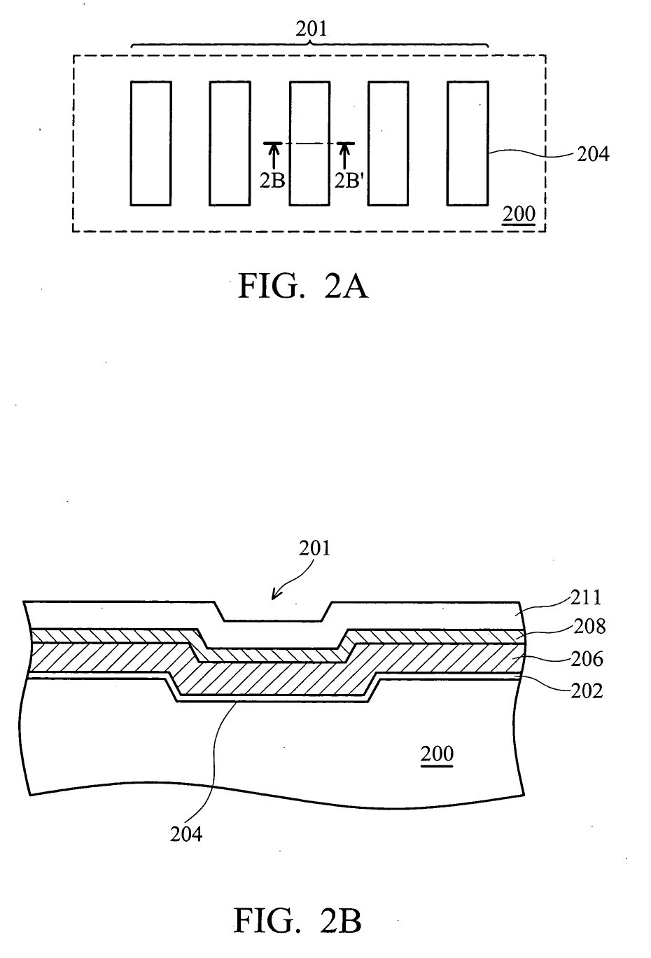

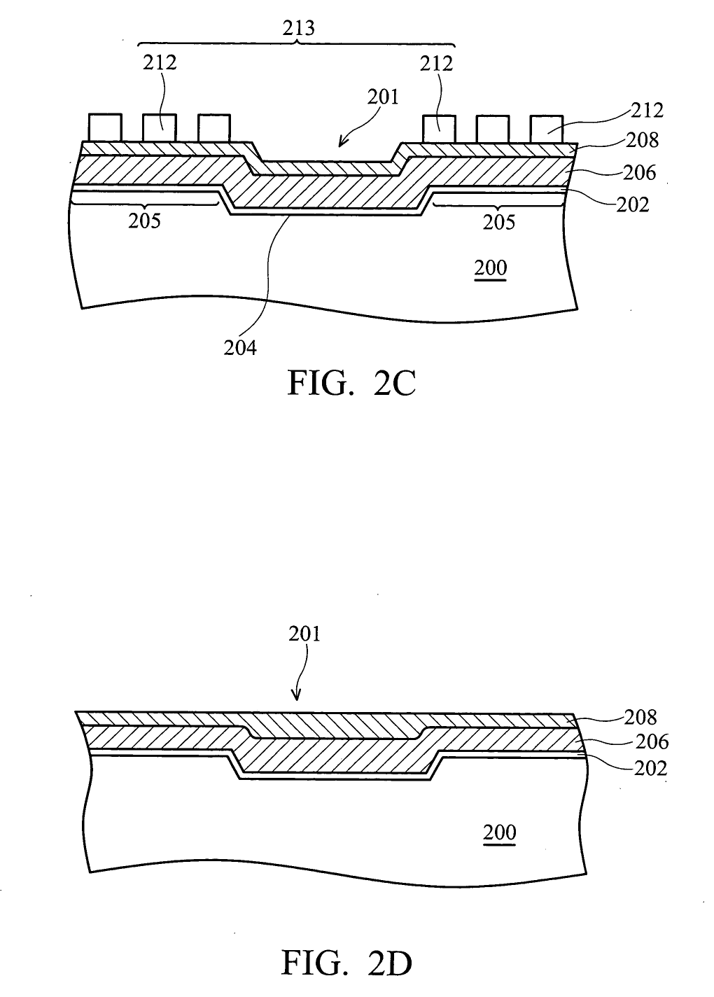

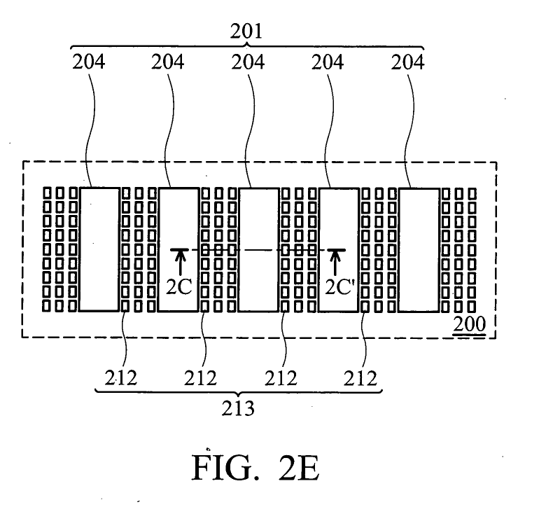

FIG. 2A is a plan view illustrating a plurality of alignment marks on a substrate of the present invention. FIGS. 2B-2C illustrate a method for protecting alignment marks used in a split gate FLASH memory fabrication process in accordance with the present invention. FIG. 2B is a cross section along line 2B-2B′ of FIG. 2A. In the following description of the invention, “substrate” comprises a semiconductor wafer, and devices and layers formed thereon. “On the substrate” refers to the exposed top layer of the semiconductor wafer, such as on a surface of the silicon wafer, on a dielectric layer, or on a metal line interconnect.

An alignment mark 201 is disposed on a substrate 200, in which the substrate 200 can be a semiconductor substrate or a glass substrate. Preferably, the substrate 200 is a silicon substrate. The alignment marks 201 comprises a plurality of trenches 204, each having a depth of 1000 Å˜2000 Å and a width of 6˜10 μm. The trenches 204 are formed by lithography and etching of the substrate 200, thus being used as alignment for exposing machines.

In the split gate FLASH memory fabrication process, a gate dielectric layer 202, a polysilicon layer 206 and a silicon nitride layer 208 are formed in order on the substrate to form gates (not shown) and over the alignment mark 201.

A protective layer 211 is formed on the silicon nitride layer 208. The protective layer 211 can be silicon oxide, silicon nitride or silicon oxide nitride. Preferably, silicon nitride with a thickness of 0.01 μm˜10 μm is utilized.

Referring to FIG. 2C and FIG. 2E, wherein FIG. 2C is a cross section along line 2C-2C′ of FIG. 2E, the protective layer 211 is patterned by lithography and etching to form a protective pattern 212 on the substrate 200 adjacent to the trenches 204. The protective pattern 213 comprises a plurality of protrusions 212 of any shape. Preferably, the protective pattern 213 comprises a plurality of rectangles 212, each preferably having a width of 0.01 μm˜10 μm and separated by a distance of 0.01 μm˜10 μm. More preferably, the rectangles 212 as small as possible as and close together as possible. The protective effect is better if the rectangles 212 are closer to the trenches 204. The size of protective pattern 213 depends on the limitation of lithography process.

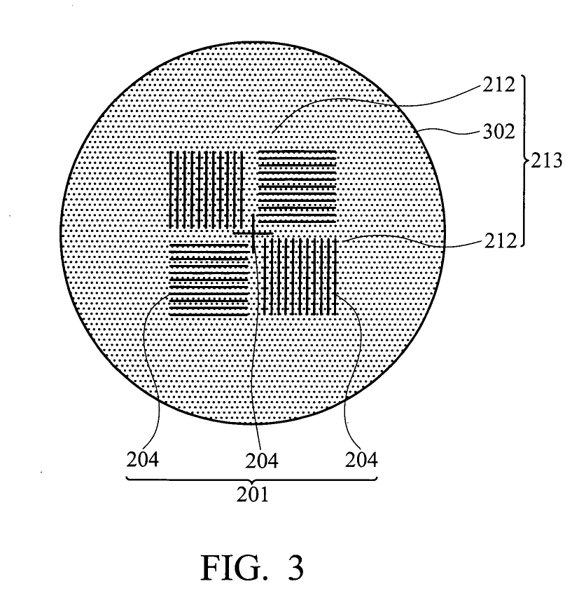

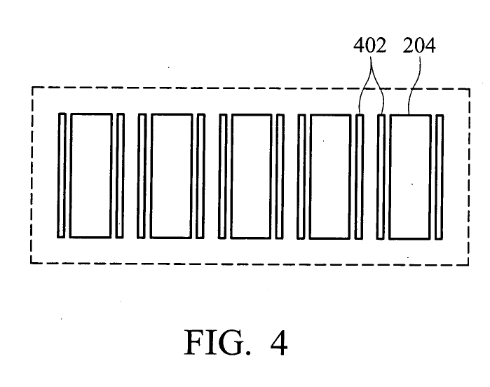

In addition, as shown in FIG. 3, the rectangles 212 can be disposed in a specific area around the protective pattern. Preferably the rectangles 212 are arranged in a circular area 302, wherein the center thereof is the alignment mark 201. The circular area preferably has a diameter of 10 μm˜1000 μm. Additionally, as shown in FIG. 4, the protective pattern 402 can comprise a plurality of bars parallel to the trenches 204 of the protective pattern.

The structure of the protective pattern is illustrated in the following paragraph. Referring to FIG. 2C and FIG. 2E, wherein FIG. 2C is a cross section along line 2C-2C′ of FIG. 2E, and an alignment mark 201 is on a substrate 200. The substrate 200 can be a semiconductor substrate and the alignment mark 201 comprises a plurality of trenches 204, preferably having a depth of 1000 Å˜2000 Å. A gate dielectric layer 202, a polysilicon layer 206 and a silicon nitride layer 208 are formed on the substrate 200 in order.

A protective pattern 213 is disposed on a substrate 200. The protective pattern comprises a plurality of protrusions 212 on the substrate 200 and adjacent to the trenches 204. Preferably, the protective pattern 213 comprises a plurality of rectangles 212, each having a width of 0.01 μm˜10 μm and separated by a distance of 0.01 μm˜10 μm. Each rectangle 212 is separated from the trenches 204 by a distance of 0.01 μm˜10 μm. The rectangles 212 are smaller, closer, and more adjacent to the trenches 204, hence they provide enhanced protection of the alignment marks 201.

Preferably, when a silicon oxide layer (not shown) on the silicon nitride layer is polished, a polishing pad is situated at the silicon nitride layer 208 over the alignment mark. If the silicon oxide layer over the alignment mark 201 is too thin due to process deviation, as shown in FIG. 2C, the protective pattern 213 can be a polish buffer, for preventing polishing the entire silicon nitride layer 208 and damaging the polysilicon layer 206. Consequently, as shown in FIG. 2D, due to the protective pattern of the present invention, the polysilicon layer 206 on the alignment mark 201 can be protected from damage during subsequent polishing or etching processes.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for protecting an alignment mark, comprising the steps of:
providing a substrate, wherein the substrate comprises a plurality of alignment marks, each comprising a plurality of trenches;
forming a protective layer on the substrate; and
patterning the protective layer to form a protective pattern on the substrate and adjacent to the alignment mark.

2. The method as claimed in claim 1, further comprising polishing the substrate wherein the protective pattern is used as a polishing buffer layer.

3. The method as claimed in claim 1, wherein the protective pattern comprises a plurality of protrusions.

4. The method as claimed in claim 3, wherein the protrusions are rectangles.

5. The method as claimed in claim 4, wherein the rectangles have a width of 0.01 μm˜10 μm.

6. The method as claimed in claim 4, wherein the rectangles are separated by a distance of 0.01 μm˜10 μm.

7. The method as claimed in claim 3, wherein the protrusions are bars along and adjacent to the trenches.

8. The method as claimed in claim 1, wherein the protective pattern is silicon nitride, silicon oxide or silicon oxide nitride.

9. The method as claimed in claim 1, further comprising a silicon layer disposed between the substrate and the protective pattern.

10. The method as claimed in claim 9, further comprising a silicon nitride layer disposed between the protective pattern and the silicon layer.

11. A structure for protecting an alignment mark, comprising:
a substrate, wherein the substrate comprises a plurality of alignment marks, each comprising a plurality of trenches; and
a protective pattern disposed on the substrate and adjacent to the alignment mark.

12. The structure as claimed in claim 11, wherein the protective pattern comprises a plurality of protrusions.

13. The structure as claimed in claim 12, wherein the protrusions are rectangles.

14. The structure as claimed in claim 13, wherein the rectangles are arranged in a circular area with the corresponding alignment mark as a center, and the circular area has a radius of 10μm˜1000μm.

15. A method for protecting an alignment mark, comprising the steps of:
providing a substrate, wherein the substrate comprises a plurality of alignment marks, each comprising a plurality of trenches, a gate dielectric layer is disposed on the alignment marks and the substrate, a polysilicon layer is disposed on the gate dielectric layer, a silicon nitride layer is disposed on the polysilicon layer and a protective layer is disposed on the silicon nitride layer;
patterning the protective layer to form a protective pattern on the substrate and adjacent to the alignment mark;
forming a least one dielectric layer on the protective pattern; and
polishing the dielectric layer, wherein the protective pattern is used as a polishing buffer layer.

16. The method as claimed in claim 15, wherein the protective pattern comprises a plurality of protrusions.

17. The method as claimed in claim 16, wherein the protrusions are rectangles.

18. The method as claimed in claim 17, wherein the rectangles are arranged in a circular area with the corresponding alignment as a center, and the circular area has a radius of 10 μm˜1000 μm.
